(19) United States
(12) Patent Application Publication
(10) Pub. No.: US 2026/0049830 A1
(43) Pub. Date: Feb. 19, 2026

(54) DIGITAL TWIN-BASED CONTROL COLLABORATION METHOD

(71) Applicant: UINFRAWAY CO., LTD., Suwon-si (KR)

(72) Inventors: Jong Hoon KIM, Yongin-si (KR); Byeong Hwa JEONG, Seongnam-si (KR)

(73) Assignee: UINFRAWAY CO., LTD., Suwon-si (KR)

(21) Appl. No.: 19/293,156

(22) Filed: Aug. 7, 2025

(30) Foreign Application Priority Data
Aug. 14, 2024 (KR) 10-2024-0108782

(51) Int. Cl. G01C 21/36

(52) U.S. Cl. CPC G01C 21/3638

(57) ABSTRACT

The present invention relates to a control collaboration method for an area that requires a patrol or inspection work, such as an urban area or a large building, in which a control room computer 10 and a mobile terminal 50 of a field agent are connected to a control server 30, and a CPS server 40 equipped with a CPS model 41 is connected to the control server 30, so that location information and video information 17 transmitted from the mobile terminal 50 are output to be combined with a model object 18 provided by the CPS model 41. Through the present invention, as information can be shared smoothly between field agents and the control room in performing control works in a wide area such as a large building, an urban area, or the like, the field agents may faithfully utilize information provided by the digital twin CPS server 40, and control room workers may accurately and quickly grasp the situations at the scene.

### CROSS-REFERENCE TO RELATED APPLICATION(S)

This application claims the benefit under 35 USC 119(a) of Korean Patent Application No. 10-2024-0108782, filed with the Korean Intellectual Property Office on Aug. 14, 2024, the disclosure of which is incorporated herein by reference in its entirety.

### BACKGROUND OF THE INVENTION

Field of the Invention The present invention relates to a control collaboration method for an area that requires a patrol or inspection work, such as an urban area or a large building, in which a control room computer 10 and a mobile terminal 50 of a field agent are connected to a control server 30, and a CPS server 40 equipped with a CPS model 41 is connected to the control server 30, so that location information and video information 17 transmitted from the mobile terminal 50 are output to be combined with a model object 18 provided by the CPS model 41.

### Background of the Related Art

As digital twin techniques are developed and distributed to replicate real objects, such as facilities and structures that already exist in reality or are planned to be installed or constructed, or urban areas or the like where these facilities and structures are gathered, as a digital data model, and to exchange information between means for detecting real objects and the digital data model through communication, digital twin-based or linked techniques are utilized in various industrial fields.

As digital twin is the digital data model described above, and is configured of a Cyber Physical System (CPS), which is constructed by merging detailed specification information into a 3D model having a shape and a structure the same as those of real objects, and a communication path, which is a path for exchanging information with objects in the real world, i.e., a communication network that performs communication with sensors mounted on various structures, facilities, or the like, and mainly used for grasping the status of large structures or facilities, grasping information on the history and plan, and performing remote inspection or simulation, it can be said that most of the functions are concentrated on the Cyber Physical System (CPS) among the components of the digital twin.

Actual application areas of the CPS and the digital twin technique may include management and monitoring works of large facilities or urban areas, and in the case of urban areas with a plurality of buildings and roads, large-scale multi-use facilities, or large buildings, it is unable or significantly limited to conduct physical experiments or actual trial use in the overall plan, design, construction, use, and maintenance. Therefore, when planning, simulated operation, and maintenance are applied through appropriate use of the digital twin CPS, various effects, such as secured safety, increased convenience, and the like, can be expected, in addition to the advantages in the economic aspect.

Accordingly, various techniques combined with digital twins in monitoring and control works are developed for the purposes of prevention of crime, firefighting, and inspection on various large structures and urban facilities, and as related prior art, there are Korean Patent No. 239066 and No. 2664178, which are techniques for monitoring and controlling facilities or urban areas.

First, Korean Patent No. 239066 is a traditional digital twin monitoring technique to which a structural computing model of digital twin is simply applied, which constructs a CPS model corresponding to a monitoring target facility, connects monitoring equipment such as cameras or sensors to the CPS model, and constantly operates the CPS model on the basis of information transmitted from the monitoring equipment to confirm operation states, deformation, or damage of the monitoring target facility.

Traditional digital twin-based facility monitoring techniques are techniques for monitoring the health of the facility itself, and although they are effective in confirming the detailed state of the facility in real time, they are disadvantageous in monitoring the situation inside or around the facility, not the facility itself.

For example, considering a control work of monitoring situations of accidents, disasters, or crimes in a monitoring target facility or area on the basis of video information at a plurality of scattered locations, as the conventional digital twin-based monitoring techniques focus on confirming the state of a facility itself, any practical benefits may not to be obtained compared to traditional CCTV-based control.

Accordingly, as a digital twin-based video monitoring method of Korean Patent No. 2664178has been developed to minimize the operation of the CPS model, strengthen the connectivity with video information, and improve the efficiency of monitoring and control works, surrounding spaces, as well as the locations of cameras transmitting video information, can be intuitively and quickly confirmed in monitoring videos of wide areas such as large buildings, urban areas, or the like.

In particular, as the digital twin-based video monitoring method of Korean Patent No. 2664178provides a model object provided by the CPS model and information on videos actually captured through fixed CCTV cameras installed in corresponding areas in a composite output format, an entity performing the control work may grasp the situations at the scene precisely and immediately, an efficient control plan can be established for a wide surrounding area.

### SUMMARY OF THE INVENTION

As a model object provided by the CPS model and information on actually captured videos are efficiently combined and provided through conventional monitoring and control techniques combined with digital twins including Patent No. 2664178, accuracy, convenience, and efficiency of control works related to crime prevention, firefighting, and inspection in large facilities or urban areas have been improved. However, due to the nature of the control works that require a high degree of collaboration between patrol or inspection agents in the field and control room workers, the conventional techniques described above may not sufficiently reflect information grasped or perceived by the field agents in performing the control works, and there is a limitation in that the unique advantages of the digital twin service may not be sufficiently utilized in terms of accuracy and efficiency in supporting and controlling the field agents.

The present invention has been conceived to allow efficient collaboration between a control room and field agents in consideration of the aforementioned problems, and there is provided a digital twin-based control collaboration method, for which a CPS server 40 including a CPS model 41 constructed therein, a control server 30 connected to a mobile terminal 50 equipped with a GPS module and a camera mounted thereon to receive location information and video information 17 and connected to the CPS server 40, and a computer 10 connected to the control server 30 and equipped with a control program mounted thereon are configured, the method comprising: a model transmission step (S11) of generating a model object 18 by operating the CPS model 41, and transmitting the model object 18 to the control server 30 by the CPS server 40 in response to a request of the control server 30; a field information transmission step (S12) of transmitting location information extracted by the GPS module and the video information 17 acquired by the camera to the control server 30 by an agent program installed in the mobile terminal 50; an object generation step (S15) of generating an agent object 51 by processing the transmitted model object 18 and location information, by the control server 30; a basic output step (S21) of transmitting the model object 18 and the agent object 51 by the control server 30 in response to a request of the control program of the computer 10, and outputting both the model object 18 and the agent object 51 by the control program; an agent selection step (S30) of transmitting identification information of the agent object 51 to the control server 30 by the control program of the computer 10 as the agent object 51 is selected; and a video output step (S40) of transmitting video information 17 corresponding to the identification information to the computer 10 by the control server 30, and outputting the video information 17 by the control program of the computer 10.

In addition, the present invention is a digital twin-based control collaboration method, in which a scene output step (S19) of transmitting the model object 18 and the agent object 51 to the mobile terminal 50 by the control server 30, and outputting the transmitted model object 18 and agent object 51 on the screen by the agent program of the mobile terminal 50 is performed, after the object generation step (S15) is performed.

### BRIEF DESCRIPTION OF THE DRAWINGS

FIG. 1 is a view showing the system configuration of the present invention.

FIG. 2 is a flowchart illustrating the present invention.

FIG. 3 is an exemplary view showing a mobile terminal screen of the present invention.

FIG. 4 is an exemplary view showing a computer screen when a basic output step of the present invention is performed.

FIG. 5 is an exemplary view showing a computer screen of the present invention, on which a model object is output three-dimensionally.

FIG. 6 is an exemplary view showing a computer screen when a video output step of the present invention is performed.

FIG. 7 is an exemplary view showing a screen on which a three-dimensional model object is output at the video output step of the present invention.

FIG. 8 is an exemplary view showing a computer screen of an embodiment in which the present invention is applied to indoor control of a building.

### DETAILED DESCRIPTION OF THE PREFERRED EMBODIMENT

The detailed configuration and implementation process of the present invention will be described below through the accompanying drawings.

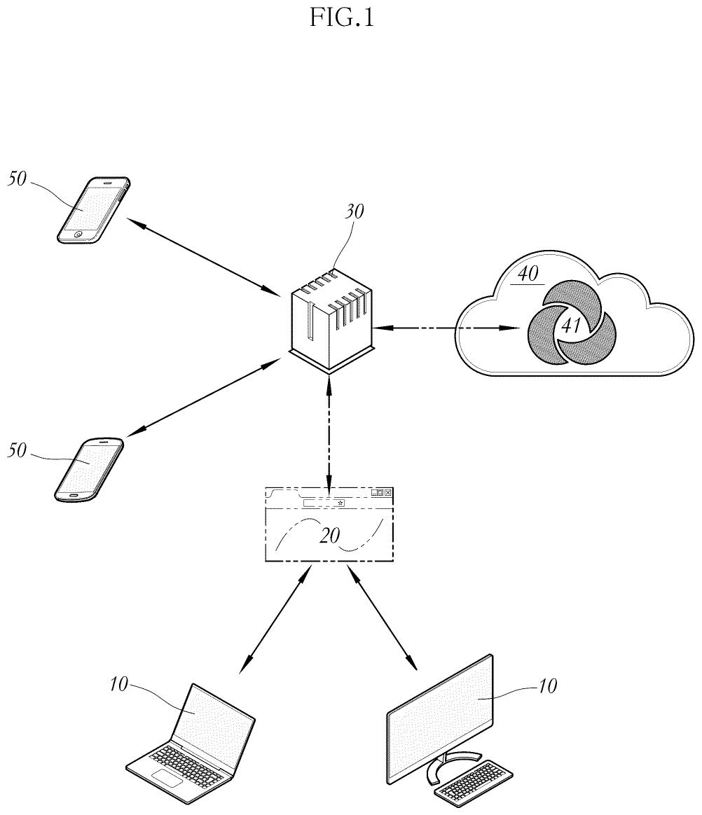

First, FIG. 1 is a view showing the configuration of components constituting a system that performs the present invention and the connection relation between the components, and as shown in the drawing, the present invention is performed by a computer 10, as an information device directly operated by a control room worker, connected to a control server 30 through a communication network such as the Internet or directly connected to the control server 30 through a dedicated line, a mobile terminal 50, as an information device used by a patrol agent or an inspection agent in the field, such as a smartphone or the like connected to the control server 30 through a wireless network and equipped with a GPS module and a camera, a cyber physical system (CPS) server 40 equipped with a CPS model 41 and connected to the control server 30, and the like.

As shown in FIG. 1, the control server 30 is a server connected to a plurality of mobile terminals 50, i.e., information devices such as a smartphone or the like of a field agent, to receive location information and video information 17 transmitted from the mobile terminals 50, and transfer signals transmitted from the control room computer 10 to the mobile terminals 50, which is a server operated by an entity that performs the control work in the patrol and inspection target urban areas, large buildings, or the like. The computer 10 connected to the control server 30 is an information device directly operated by a control room worker as described above, and performs a function of outputting the video information 17 of the mobile terminal 50 transmitted from the control server 30 and a function of transmitting control commands of the control room worker to the control server 30.

Although the control server 30 and the computer 10 are configured as separate information device hardware connected through a communication network in FIG. 1, in the present invention, the control server 30 and the computer 10 are entities that act as a server and a client, respectively, and may be constricted as software on the same hardware.

However, when the control server 30 and the computer 10 constitute a client-server system and are configured in a state of connecting separate hardware devices through a communication network as shown in FIG. 1, a plurality of users may utilize the control server 30.

In addition, as shown by imaginary lines in FIG. 1, when a web server function is given to the control server 30, or a webpage 20 controlled by the control server 30 is constructed by connecting a separate web server in a hardware or software form although not specified in the drawing, easy access to the control server 30 is possible by utilizing a general computer 10 equipped with a browser and the Internet.

Particularly, in processing the model object 18 described below and the video information 17 and transmitting control commands, which are mainly performed in information processing between the control server 30 and the computer 10, all the processes of the present invention described below can be smoothly performed using only a browser widely distributed to general personal computers 10 without installing a separate dedicated application program in the computer 10, through the configuration of the webpage 20 that mediates the control server 30 and the computer 10.

The connection relation between the computer 10 and the control server 30 described above can be equally applied to the connection relation between the control server 30 and the CPS server 40, and the CPS server 40 is also constructed as an independent entity having hardware separate from the control server 30 and may be connected through a communication network such as the Internet or the like, and the CPS server 40 and the control server 30 may also be constructed in the same hardware.

The CPS server 40 and the control server 30 separately act as a server and a client in carrying out the present invention. The CPS server 40 operates the CPS model 41 mounted thereon and provides information such as the model object 18 and the like to the control server 30 in response to a request of the control server 30, and when the control server 30 requests the CPS server 40 to operate the CPS model 41, it provides basic condition information needed for operating the CPS model 41.

In conclusion, the connection between the components of the present invention shown in FIG. 1 means a logical connection, not a physical connection. All the webpage 20, the control server 30, and the CPS server 40 may be constructed in a single server hardware in the form of individual server programs, and each server program may be constructed to be physically separated in different server hardware or storage. As shown in the drawing, the CPS server 40 may be implemented in various forms, such as being constructed on the basis of cloud computing.

As described above, the mobile terminal 50 used by the field agent in the present invention is an information device that can extract its own location information in real time as it may connect to a wireless network and is equipped with a GPS module, and produce video information 17 that captures the situations at the scene or the like as it is equipped with a camera, and as most of mobile devices such as smartphones or tablet PCs currently on the market are equipped with functions of accessing a wireless network, receiving and processing GPS signals, and capturing videos as described above, general smartphones may be applied as the mobile terminal 50 in the present invention.

In addition, as the general smartphone described above is a mobile station of a mobile communication network and may access wireless LANs, it may access the Internet and the control server 30 of the present invention through a wireless network including these mobile communication networks and wireless LANs.

In the present invention, the location information and the video information 17 transmitted from the mobile terminal 50 are collected by the control server 30 and finally transmitted to the computer 10 to be output, and also the model object 18 generated by the CPS model 41 mounted on the CPS server 40 is finally transmitted to the computer 10 and the mobile terminal 50 via the control server 30 to be output.

Accordingly, an application program that may communicate with the control server 30 and process and output the location information, video information 17, and the model object 18 transmitted from the control server 30 needs to be mounted on the computer 10 that the control room worker uses, and in the present invention, this is referred to as a control program, and an application program that may access the control server 30, transmit the captured location information and video information 17 to the control server 30, and output the model object 18 and a control message provided by the control server 30 needs to be mounted on the mobile terminal 50, and in the present invention, this is referred to as an agent program.

Although such a control program may be developed as a separate dedicated program specialized for the functions described above, a general browser may be employed as the control program and perform the functions described above, and the agent program may also be developed as a separate dedicated smartphone application, and a browser mounted on the smartphone may also be applied as the agent program.

Here, the browsers mounted on the computer 10 and the mobile terminal 50 are general commercial browsers capable of performing the present invention and viewing general web-based electronic documents on the Internet sites. However, a plug-in program capable of processing and outputting the location information and the video information 17 and processing and outputting products of the digital twin CPS model 41 can be mounted, or modification of the browser may be preceded in the form of function patches, sub-programs, or program modules of the browser, and despite the modification of a general browser, the browser used in the present invention is modified on the basis of a general commercial browser, and it can be said that the browser's identity as a processor of web standards information is maintained.

In the present invention, the CPS model 41 constructed in the CPS server 40 is constructed by combining the locations, shapes, structures, and specification information of structures constituting a control target, i.e., an urban area in a patrol target area or a large building to be inspected, and the CPS model 41 generates the model object 18 in the form of a three-dimensional model displayed in a visual form under the control of the CPS server 40.

In addition, in the present invention, smartphones or the like on the market may be applied as the mobile terminal 50 that generates the video information 17 actually photographing real control target objects as described above. When a digital camera basically mounted on the smartphones on the market captures the situations at the scene or the like, an agent program of the mobile terminal 50 transmits the captured video information 17 to the control server 30. Identification information set for each mobile terminal 50 is recorded in the control server 30, and the identification information is unique information assigned to each mobile terminal 50 to identify each mobile terminal 50, i.e., each field agent, and the control server 30 may grasp the source and location of the received video information 17 through the identification information.

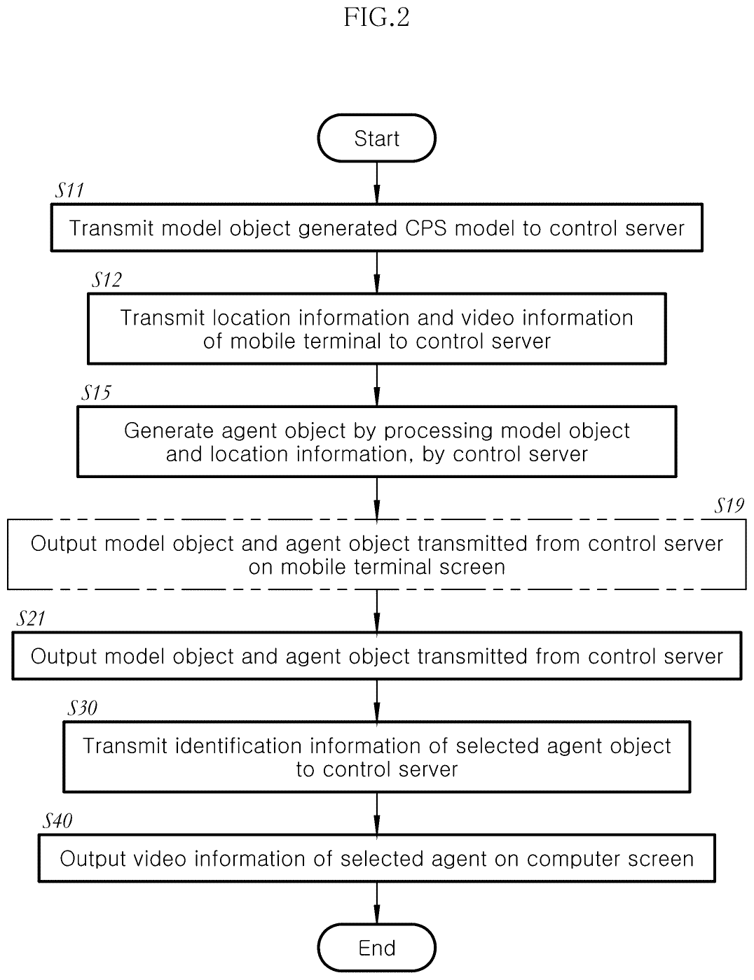

As described above, the present invention provides a digital twin-based control collaboration method performed by a system configured of a CPS server 40 including a CPS model 41 constructed therein, a control server 30 connected to the mobile terminal 50 where an agent program is installed to receive location information and video information 17 and connected to the CPS server 40, and a computer 10 connected to the control server 30 and equipped with a control program, and as shown in FIG. 2, the method begins with a model transmission step (S11) of generating a model object 18 by operating the CPS model 41, and transmitting the model object 18 to the control server 30 by the CPS server 40 in response to a request of the control server 30.

The CPS model 41 is a three-dimensional model established for patrol or inspection targets managed by the operating entity of the control server 30, i.e., facilities of urban areas or large buildings, and the locations, shapes, structures, and specifications of the structures, members, and various attachments constituting the patrol or inspection targets are recorded in the memory device of the CPS server 40 as three-dimensional information to form the CPS model 41.

At the model transmission step (S11), the request of the control server 30 is to initiate a process of generating a model object 18 in a monitoring target as the CPS server 40 operates the CPS model 41, and at the same time, it means a process of transmitting information specifying a regional range, a building, or the like that sets a control target or a control target area to the CPS server 40 by the control server 30. Here, the process of specifying a control target area, a building, or the like is not a separately established model as the CPS model 41 is specialized for performing the present invention, but a process that is necessarily required when the present invention borrows a CPS model 41 previously constructed for general or other purposes, such as a public CPS or the like.

In addition, in addition to performing the model transmission step (S11) described above, a field information transmission step (S12) of transmitting its own location information extracted by the GPS module and the video information 17 acquired by the camera to the control server 30 by the agent program installed in the mobile terminal 50 is performed.

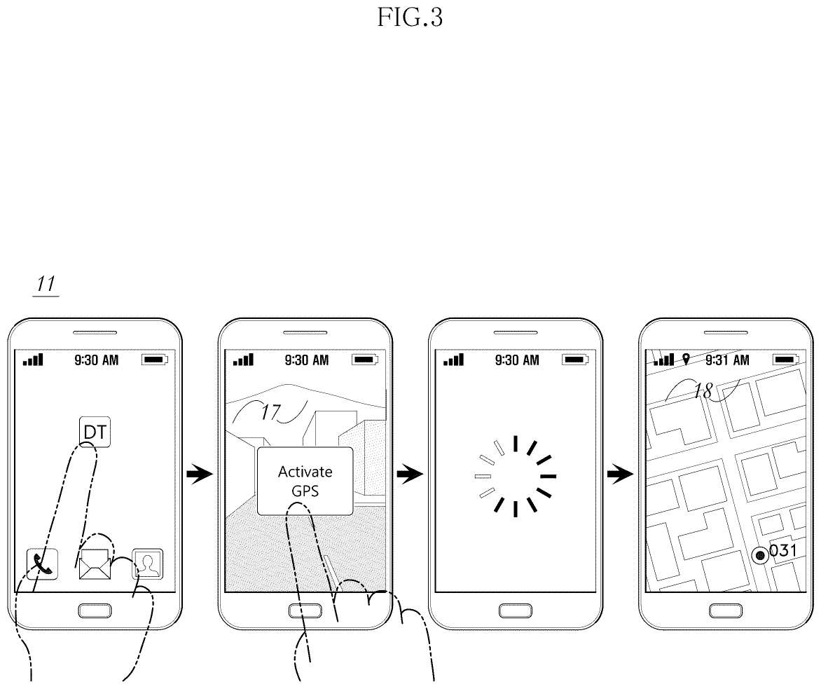

The field information transmission step (S12) may be performed in a manner in which a field patrol agent or an inspection agent, who is a user of the mobile terminal 50, executes an agent program installed in his or her mobile terminal 50 as an application program, and activates built-in cameras and the GPS module, as shown in FIG. 3. Here, since activation of the cameras and the GPS module is a function that requires higher authority in the operating system of the mobile terminal 50 such as a smartphone or the like, a procedure of confirming the consent of the user may be performed as shown in the drawing.

In this way, when the model transmission step (S11) and the field information transmission step (S12) are performed, an object generation step (S15) of generating an agent object 51 by processing the transmitted model object 18 and processing the identification information and location information described above by the control server 30 is performed. Here, generation of the agent object 51 is establishing the identification information and location information as objects included in the CPS model 41 in order to specify an object corresponding to the mobile terminal 50, i.e., an individual agent, distinguished from all model objects 18 generated by the CPS model 41, and grasp the location of the agent.

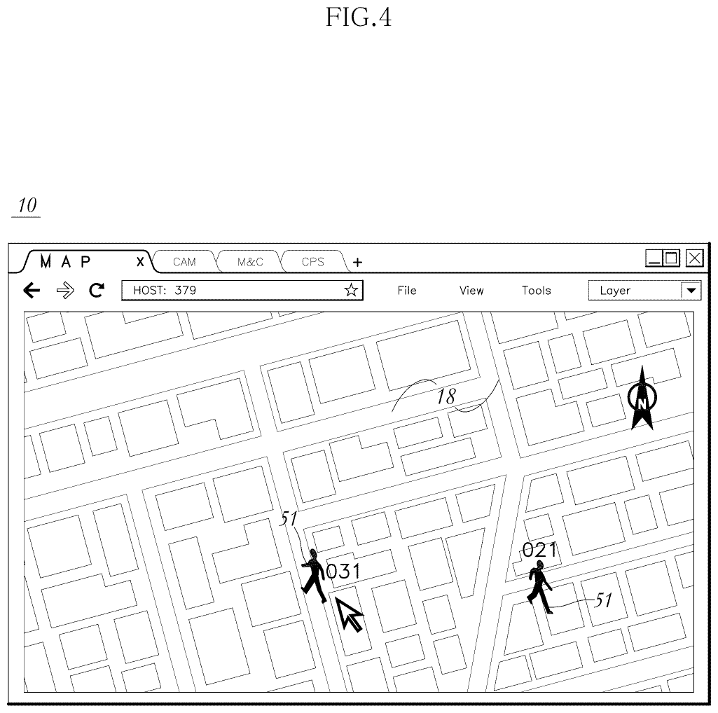

When the object generation step (S15) is completed, a basic output step (S21) of transmitting the model object 18 and the agent object 51 by the control server 30 in response to a request of the control program of the computer 10, and outputting both the model object 18 and the agent object 51 by the control program is performed, and an example of the screen of the computer 10 on which the basic output step (S21) has been performed is shown in FIG. 4.

Like the meaning in the dictionary, the basic output step (S21) is a step of providing basic information to the user to carry out the present invention described below, and in FIG. 4, agent objects 51 for confirming field agents scattered in corresponding areas are shown, together with general information on the control target area provided in the form of a map.

In the embodiment shown in FIG. 4, the present invention is applied when the control target is an urban area, and a floor plan of the urban area is displayed on the screen of the computer 10, in which mobile terminals 50, i.e., marks that can confirm the location of each field agent, are displayed in the form of a pictogram shaped like a human body. Here, the floor plan of the urban area may be implemented only through an extremely simple process of simplifying a three-dimensional model object 18 generated by the CPS model 41 into a two-dimensional model object 18, and the agent object 51 may also be simplified in the form of a pictogram described above to confirm only the locations.

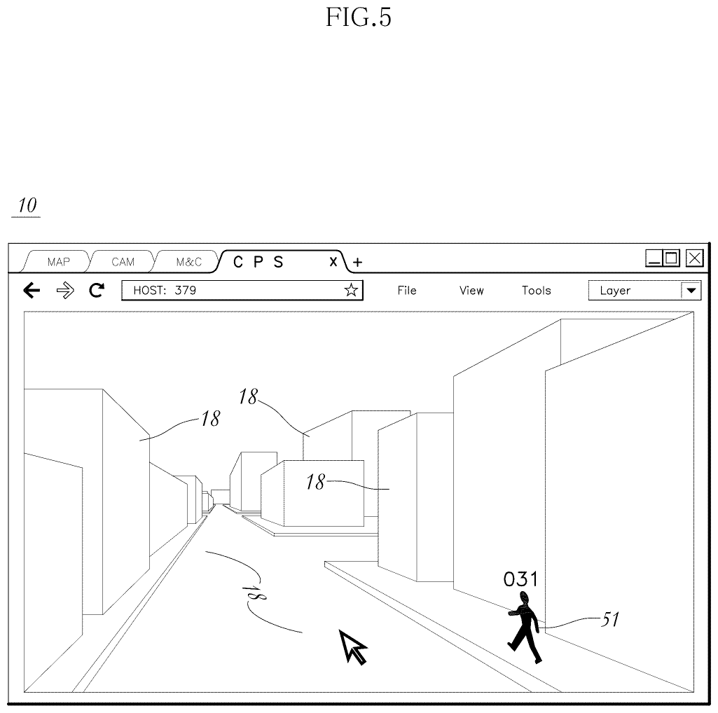

Meanwhile, FIG. 5 is a view showing that the model object 18 is configured as a three-dimensional structure rather than a two-dimensional plane, and the agent object 51 of an agent working in the model object 18 is also expressed in a three-dimensional space, and this doubles the sense of reality.

Subsequently, as shown in FIG. 2, as the agent object 51 is selected, an agent selection step (S30) of transmitting the identification information of the agent object 51 to the control server 30 by the control program of the computer 10 is performed. The agent selection step (S30) is performed as the user, i.e., a control room worker, selects the agent object 51 on the screen of the computer 10 through an operation of clicking or the like while the basic output step (S21) described above is performed. After the agent selection step (S30), a video output step (S40) of transmitting video information 17 corresponding to the identification information to the computer 10 by the control server 30, and outputting the video information 17 by the control program of the computer 10 is performed.

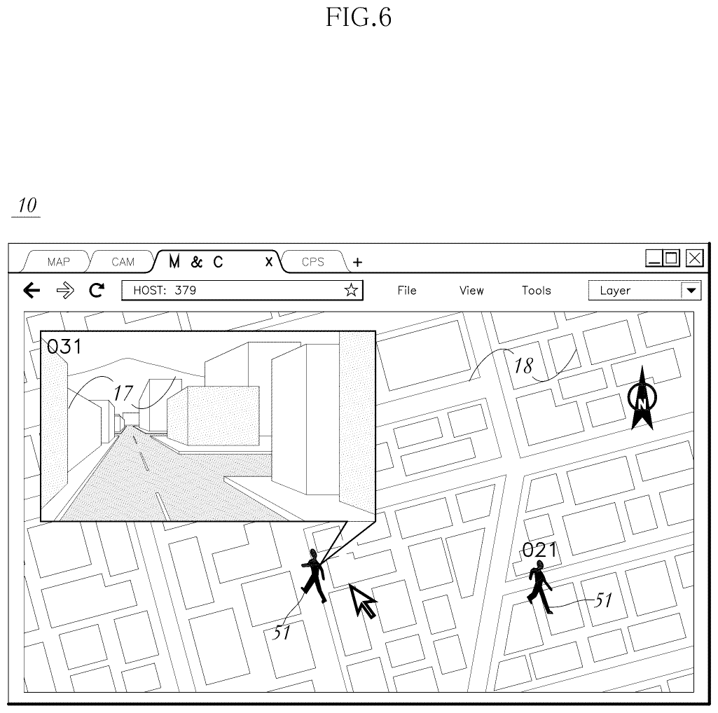

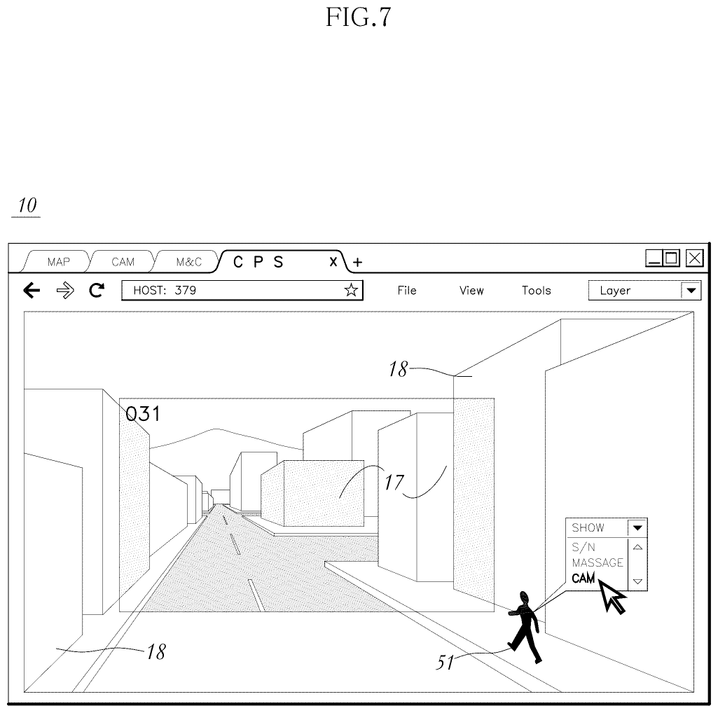

The screen of the computer 10 in a situation of performing the agent selection step (S30) and the video output step (S40) is shown in FIGS. 6 and 7. FIG. 6 shows a view of outputting the video information 17 transmitted from a corresponding mobile terminal 50 through the screen of the computer 10 as the user selects a specific pictogram, i.e., agent object 51, on the screen of the basic output step (S21) in the form of a traditional control screen as shown in FIG. 4 described above, and FIG. 7 shows a view of outputting the video information 17 transmitted from a corresponding mobile terminal 50 to be overlapped with the model object 18 as the user selects the agent object 51 on the screen in a situation in which the model object 18 and the agent object 51 are three-dimensionally displayed on the screen of the computer 10 as shown in FIG. 5 described above.

In this way, as the model object 18 generated by the CPS model 41 and the video information 17 actually capturing the field using the mobile terminal 50 of the field agent are output together as shown in FIGS. 6 and 7, the sense of reality of the control room worker can be improved dramatically, and an experience similar to performing a virtual patrol in accompany with a field agent can be provided.

In addition, after the object generation step (S15) is performed, a scene output step (S19) of transmitting the model object 18 and the agent object 51 to the mobile terminal 50 by the control server 30, and outputting the transmitted model object 18 and agent object 51 on the screen by the agent program of the mobile terminal 50 may be performed. As the field agent may objectively grasp his/her location in the model object 18, as well as confirming the model object 18, through the screen of his/her mobile terminal 50, efficiency and safety of patrol the work can be secured through the scene output step (S19).

In particular, as the work can be controlled and divided efficiently through a series of the processes described above while the control room workers and field agents share the same information in real time, a high degree of collaboration effect can be obtained in performing the control and field works.

In addition, as shown in FIGS. 6 and 7 described above, since an experience similar to performing a virtual patrol in accompany with a field agent can be provided on the control screen output through the control room computer 10, the present invention may be usefully utilized for education and training of field agents.

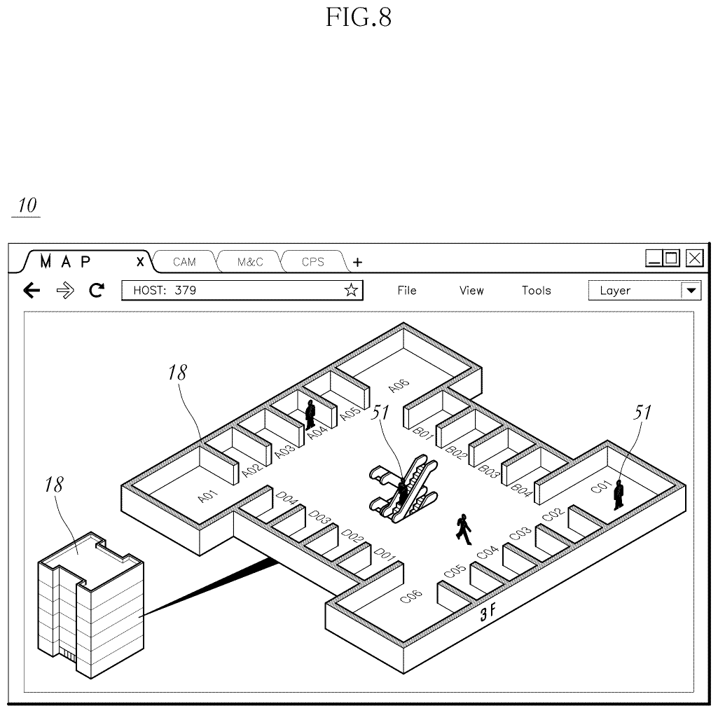

Meanwhile, FIG. 8 is a view showing the screen of the computer 10, assuming a situation of applying the present invention to a control work in a space inside a building, rather than an open space such as an urban area or the like. In this case, location information may be calculated on the basis of a wireless LAN access point, signal sensitivity, or the like of the mobile terminal 50 inside a building, and thus, accurate identification of the location and efficient guidance and control of the field agents are possible even in a space inside a building, where the location of individual field agents is difficult to identify compared to an open space.

Through the present invention, as information can be shared smoothly between field agents and the control room in performing control works in a wide area such as a large building, an urban area, or the like, the field agents may faithfully utilize information provided by the digital twin CPS server 40, and control room workers may accurately and quickly grasp the situations at the scene.

Therefore, since rapid, accurate, and efficient control is possible in a wide area, and accurate and rapid transfer of information and propagation of situation to the field agents are possible, various situations that may occur in a patrol and inspection work can be handled immediately and efficiently, while improving the efficiency of the patrol and inspection work.

### DESCRIPTION OF SYMBOLS

10: Computer
17: Video information
18: Model object
20: Webpage
30: Control server
40: CPS server
41: CPS model
50: Mobile terminal
S11: Model transmission step
S12: Field information transmission step
S15: Object generation step
S19: Scene output step
S21: Basic output step
S30: Agent selection step
S40: Video output step

What is claimed is:

1. A digital twin-based control collaboration method, for which a CPS server 40 including a CPS model 41 constructed therein, a control server 30 connected to a mobile terminal 50 equipped with a GPS module and a camera mounted thereon to receive location information and video information 17 and connected to the CPS server 40, and a computer 10 connected to the control server 30 and equipped with a control program mounted thereon are configured, the method comprising:
a model transmission step (S11) of generating a model object 18 by operating the CPS model 41, and transmitting the model object 18 to the control server 30 by the CPS server 40 in response to a request of the control server 30;
a field information transmission step (S12) of transmitting location information extracted by the GPS module and the video information 17 acquired by the camera to the control server 30 by an agent program installed in the mobile terminal 50;
an object generation step (S15) of generating an agent object 51 by processing the transmitted model object 18 and location information, by the control server 30;
a basic output step (S21) of transmitting the model object 18 and the agent object 51 by the control server 30 in response to a request of the control program of the computer 10, and outputting both the model object 18 and the agent object 51 by the control program;
an agent selection step (S30) of transmitting identification information of the agent object 51 to the control server 30 by the control program of the computer 10 as the agent object 51 is selected; and
a video output step (S40) of transmitting video information 17 corresponding to the identification information to the computer 10 by the control server 30, and outputting the video information 17 by the control program of the computer 10.

2. The method according to claim 1, wherein after the object generation step (S15) is performed, a scene output step (S19) of transmitting the model object 18 and the agent object 51 to the mobile terminal 50 by the control server 30, and outputting the transmitted model object 18 and agent object 51 on the screen by the agent program of the mobile terminal 50 is performed.
